(19) United States
(12) Patent Application Publication
(10) Pub. No.: US 2007/0158134 A1
(43) Pub. Date: Jul. 12, 2007

(54) Speaker cabinet acoustics control mechanism

(76) Inventor: Steven M. Fryette, Valley Glen, CA (US)

Correspondence Address: ERIC D. JORGENSON, 1457 KING ROAD, HINCKLEY, OH, 44233, US

(21) Appl. No.: 11/330,735

(22) Filed: Jan. 11, 2006

(51) Int. Cl. A47B 81/06; H05K 5/00

(52) U.S. Cl. 181/199; 181/148

(57) ABSTRACT

A speaker cabinet control mechanism that facilitates control of speaker cabinet tonal quality. A bracing structure is applied to a baffle panel that changes the resonant frequency of the baffle panel thereby changing the overall tonal quality of the speaker cabinet. The bracing structure allows the conventional sound post and the problems associated therewith to be eliminated while retaining the vintage sound of the cabinet. Utilization of the bracing structure in combination with the design of the cabinet back panel further enhances control over the overall cabinet tonal quality. The bracing structure can be designed to be manually and automatically controllable with further enhancements.

### TECHNICAL FIELD

This invention relates to audio speaker enclosures, and more specifically, to a mechanism for controlling sound quality of an audio speaker enclosure.

### BACKGROUND

Over the past few years, the sound characteristics of vintage cabinets have become more popular. Vintage speaker cabinets are generally looser, in that they are constructed in a fashion which allows air leakage around and through seams and joints. Accordingly, the recent emphasis in speaker cabinet construction has been on looser (or “sloppier”) sounding cabinets.

In an attempt to maintain speaker tonal quality the conventional speaker enclosure includes a sound post which provides structural stability to improve low frequency performance. In other words, the sound post can be utilized to mitigate unwanted vibrations from a speaker baffle panel, thereby negatively affecting speaker tonal quality. The sound post is typically constructed perpendicular to the baffle panel and extends from the baffle panel to a back panel of the cabinet enclosure.

In order for the sound post to work well, it needs to be loaded. In other words, a suitable amount of longitudinal compression (or loading) needs to be brought to bear on it. This is because when the cabinet speakers are driven sufficiently loud, the amount of air pressure that can build inside the cabinet chamber from speaker cone oscillations can cause the baffle panel and the back panel to be pushed away from each other, thereby exceeding the length of the sound post. This can cause a vibration between an end of the sound post and the panel to which it attaches (e.g., the back panel end and the back panel of the enclosure). Thus, the ends of the sound post should be securely fastened (e.g., screwed) to the respective panels, and should be slightly longer then the internal spatial dimension of the cabinet over which it extends so as to provide some load on it. In other words, the sound post should be loaded during installation to exhibit a slight bow. For aesthetic purposes, it is not desirable for the speaker cabinet to bow on the front (or baffle) panel, so the sound post is typically secured on a front framing structure (e.g., speaker baffle panel) that does not bow under the post loading. Accordingly, if at all in conventional speaker cabinets, panel bowing is allowed to occur on the back speaker panel.

Speaker cabinet builders invariably seem to manufacture inferior cabinets by not properly loading and/or constructing the sound post. Additionally, over time, the sound post can dry out, and thus, shrink, affecting or eliminating any load originally placed on the post. Consequently, the post eventually can work loose at one or both ends thereby causing rattling in the cabinet at high audio volume or sound pressure levels. Additionally, the post can be damaged during production fabrication (e.g., the post is split). Thereafter, if the sound post dries out, the split can widen, again, further damaging the intended function of the post. Still further, no matter how much effort is employed to specify and construct speaker cabinets with the desired wood, the sound post is typically made of inferior wood that can degrade the sound quality of the cabinet over time.

The sound post is a design feature that introduces a variable which has heretofore been difficult to control in conventional speaker systems when the desire is to produce a cabinet with a consistent sound characteristic. Accordingly, what is desired is an improved speaker cabinet design that can overcomes the shortcomings of the conventional speaker designs and provides control of the cabinet tonal performance.

### SUMMARY

The following presents a simplified summary in order to provide a basic understanding of some aspects of the disclosed innovation. This summary is not an extensive overview, and it is not intended to identify key/critical elements or to delineate the scope thereof. Its sole purpose is to present some concepts in a simplified form as a prelude to the more detailed description that is presented later.

The innovation includes a speaker cabinet control mechanism for controlling speaker cabinet tonal quality. A bracing structure is applied to a baffle panel that changes the resonant frequency of the baffle panel thereby changing the overall tonal quality of the speaker cabinet. The bracing structure allows the conventional sound post and the problems associated therewith to be eliminated while retaining the vintage sound associated with some conventional cabinet designs. Utilization of the bracing structure in combination with the design of the cabinet back panel further enhances control over the overall cabinet tonal quality. The bracing structure can be designed to be manually and automatically controllable with further enhancements.

Accordingly, the invention disclosed and claimed herein, in one aspect thereof, comprises a speaker enclosure that includes a panel for supporting a speaker, and a bracing structure attached to the panel for controlling vibratory signals induced into the panel when the speaker oscillates. The bracing structure as applied herein provides a sound associated with looser response on the bottom end of the audio spectrum while maintaining a tightly constructed cabinet.

In another aspect of the subject invention, a manual adjustment mechanism can be mounted such that adjustment of loading on the bracing structure can be obtained.

In yet another aspect thereof, an electromechanical interface is coupled to the manual adjustment mechanism for automated control of the bracing structure loading.

To the accomplishment of the foregoing and related ends, certain illustrative aspects of the disclosed innovation are described herein in connection with the following description and the annexed drawings. These aspects are indicative, however, of but a few of the various ways in which the principles disclosed herein can be employed and is intended to include all such aspects and their equivalents. Other advantages and novel features will become apparent from the following detailed description when considered in conjunction with the drawings.

### BRIEF DESCRIPTION OF THE DRAWINGS

FIG. 1 illustrates an isometric of a speaker cabinet or enclosure that employs a bracing structure for controlling speaker cabinet tonal quality in accordance with the subject innovation.

FIG. 2 illustrates an exemplary v-shaped bracing structure for controlling speaker cabinet tonal quality in accordance with the subject innovation.

FIG. 3 illustrates an isometric of one exemplary speaker cabinet that employs a bracing structure in accordance with the subject innovation.

FIG. 4 illustrates a variation on the v-shaped bracing structure of FIG. 2.

FIG. 5 illustrates an alternative variation on the v-shaped bracing structure of FIG. 2.

FIG. 6 illustrates an alternative variation on the v-shaped bracing structure of FIG. 2 that employs two separate pieces.

FIG. 7 illustrates an alternative variation on the v-shaped bracing structure of FIG. 2 that removes material at the interfacing edge.

FIG. 8 illustrates an alternative brace similar to the v-shaped bracing structure of FIG. 7 that adds a hole through the thickness dimension.

FIG. 9 illustrates an alternative brace similar to the v-shaped bracing structure of FIG. 2 that moves the apex off center thereby shifting the center of mass to a different location.

FIG. 10 illustrates a baffle panel wherein a bracing structure is attached in a vertical orientation to achieve the desired cabinet tonal quality in accordance with an innovative aspect.

FIG. 11 illustrates a cross bracing structure that can be employed for controlling the cabinet tonal quality.

FIG. 12 illustrates a two-speaker cabinet having a baffle panel to which is attached a bracing structure for controlling the cabinet tonal quality.

FIG. 13 illustrates a speaker cabinet that employs a bracing structure on the back panel for controlling cabinet tonal quality.

FIG. 14 illustrates an effect that loading can have on a bracing structure in accordance with an innovative aspect.

FIG. 15 illustrates a top-down view of a bracing structure as mounted on a baffle panel and the outward bow that can be exhibited in accordance with the subject invention.

FIG. 16 illustrates a top-down view of the bracing structure of FIG. 5 as mounted on the baffle panel and the outward bow that can be exhibited in accordance with another aspect.

FIG. 17 illustrates a top-down view of a bracing structure system that employs a manual adjustment mechanism for adjusting loading thereof to affect the tonal quality of the associated cabinet.

FIG. 18 illustrates a side view of a bracing structure and baffle panel system that employs a manual adjustment mechanism for adjusting loading to effect the tonal quality of the associated speaker cabinet.

FIG. 19 illustrates an exemplary implementation of an automated tonal control mechanism for controlling the speaker cabinet tonal quality.

FIG. 20 illustrates an alternative automated implementation for cabinet sound quality control in accordance with the subject innovation.

FIG. 21 illustrates a schematic block diagram of a cabinet tonal control system wherein an audio amplifier interfaces to the control system of the electromechanical interface for control of the cabinet tonal quality in accordance with another aspect.

FIG. 22 illustrates a flow diagram that represents a methodology of controlling speaker cabinet tonal quality in accordance with an innovative aspect.

FIG. 23 illustrates a flow diagram that represents a methodology of maintaining speaker cabinet tonal quality in accordance with an innovative aspect.

FIG. 24 illustrates a flow diagram that represents a methodology of automatically adjusting speaker cabinet tonal quality in accordance with an innovative aspect.

### DETAILED DESCRIPTION

The innovation is now described with reference to the drawings, wherein like reference numerals are used to refer to like elements throughout. In the following description, for purposes of explanation, numerous specific details are set forth in order to provide a thorough understanding thereof. It may be evident, however, that the innovation can be practiced without these specific details. In other instances, well-known structures and devices are shown in block diagram form in order to facilitate a description thereof.

Note that in this description, references to “one implementation” or “one embodiment” or “an embodiment” or “an implementation” mean that the feature being referred to is included in at least one embodiment of the invention. Further, separate references to “one implementation” or “one embodiment” in this description do not necessarily refer to the same embodiment; however, neither are such embodiments mutually exclusive, unless so stated and except as will be readily apparent to those skilled in the art. For example, a feature, structure, act, etc., described in one implementation can also be included in other implementations. Accordingly, the instant invention can include a variety of combinations and/or integrations of the implementations described herein.

The instant invention overcomes the shortcomings of the conventional speaker designs by eliminating the sound post and providing a bracing structure on the speaker baffle for controlling cabinet tonal quality. Additionally, the cabinet back panel design (e.g., the panel thickness and material) can be considered in combination with the bracing structure to further control the cabinet tonal quality. These changes facilitate approaching or duplicating the performance of a conventional cabinet that uses the sound post when operating as originally intended. Accordingly, by employing the bracing structure separately or in combination with a change in the design of the back panel, the desired sound quality can be achieved in an acoustically active speaker cabinet.

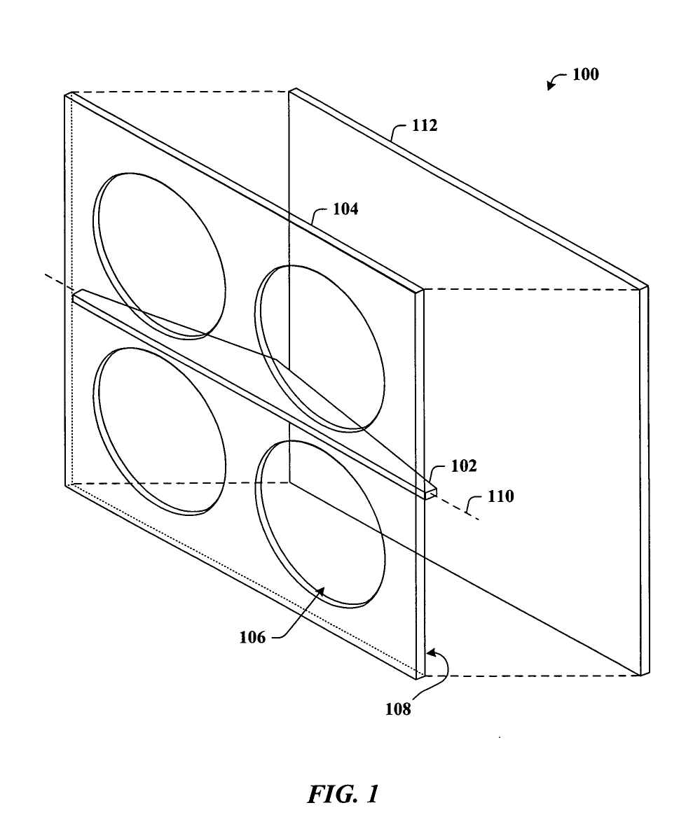

Referring initially to the drawings, FIG. 1 illustrates an isometric of a speaker cabinet or enclosure 100 that employs a bracing structure 102 for controlling speaker cabinet tonal quality in accordance with the subject innovation. The bracing structure 102 mounts to a speaker baffle panel 104 that supports one or more audio speakers (not shown) which mount into baffle speaker holes 106. In this implementation, the bracing structure 102 mounts flush to an inside (or inward facing) surface 108 of the baffle panel 104, and extends across the baffle panel 104. The bracing structure 102 can be mounted to points that are between all outside cabinet panels (not shown). The method of mounting the bracing structure 102 to the inside surface 108 can include, but is not limited to, fasteners (e.g., screws, nuts/bolts, rivets, . . . ) suitable for speaker cabinet construction, clamps, and/or bonding material (e.g., epoxy), for example. Additionally, the number of mounting points for attaching the bracing structure 102 is at the discretion of the builder, but in many instances, can be three points.

As will be described hereinbelow, the bracing structure 102 can also be installed in a loaded condition whereby compressive force is applied along a longitudinal axis 110 during the mounting process. In such a case, the bracing structure 102 can exhibit a slight bend or bow.

An additional aspect of the cabinet 100 which can be utilized to influence cabinet tone quality is design of a back panel 112. For example, the back panel thickness, type of material, and technique for securing the back panel 112 to the other cabinet framework during cabinet construction can influence the cabinet tone quality.

It is to be understood that use of the bracing structure 102 to control cabinet tone quality or the combination of the bracing structure 102 and back panel 112 can be selected according to the desired series of cabinets. For example, in one series of cabinets, the bracing structure 102 can be employed to operate alone, while in another style of cabinets, the bracing structure and back panel design are employed in combination to control the tone quality. Thus, a variety of sound qualities can be obtained by adjusting at least one or both of these parameters: the bracing structure 102 and the design (e.g., thickness) of the back panel 112. Additionally, the design parameters of the bracing structure 102 and how it is attached to the baffle panel 104 and/or back panel 112 can all affect the tonal behavior of the cabinet 100.

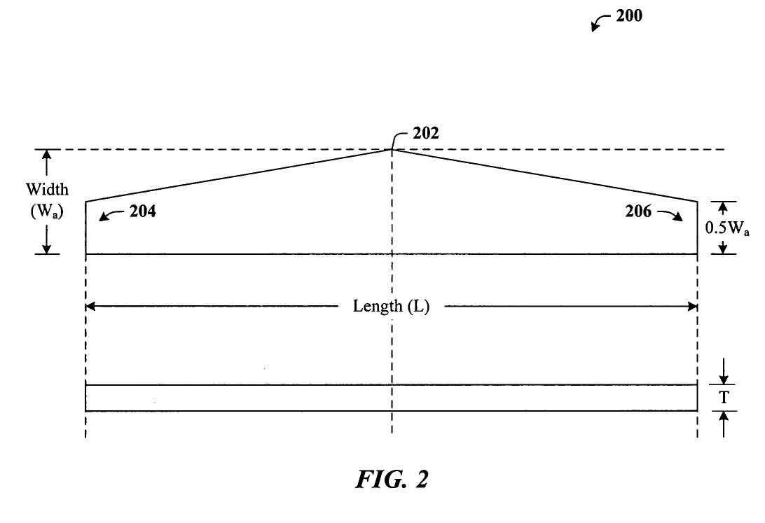

FIG. 2 illustrates an exemplary v-shaped bracing structure 200 for controlling speaker cabinet tonal quality in accordance with the subject innovation. In this particular implementation, the structure 200 has an apex width Wₐ at an apex 202, which apex 202 is the point of greatest width and which is centered approximately equidistant from the structure ends; a first end 204 and a second end 206. The end widths Wₑ, in this example, are each about one-half (0.5W) of the apex width Wₐ. However, it is not a requirement that the ends (204 and 206) be of the same width, or even one half of the apex width Wₐ. For example, where the material employed in the structure 200 has sufficient strength (e.g., plastic, graphite, metal, . . . ), the structure widths at the ends (204 and 206) can be less than other materials that may require a greater width for structural integrity and/or the desired cabinet tonal effect.

The structure 200 is shown having a thickness T, which can be any suitable thickness for the desired tonal effect and for structural integrity of the bracing structure 200, as well as based on the type of material employed. For example, if the structure material is graphite-based, the thickness may be reduced relative to a wood material, which may require a greater thickness, or vice versa. In any case, the thickness T can vary based on the material employed and the tonal quality desired.

The structure 200 also has a length L, which can be of a length that extends from one edge of the baffle panel to the opposite baffle panel edge. In another implementation, the length L is less than the distance between opposing baffle panel edges to which it is attached.

No formula is provided herein to obtain the desired sound quality, although this can be determined and utilized in a production environment, for example. Accordingly, the sound can be a personal attribute that is tuned by the artisan when the speaker cabinet is constructed.

Here, the bracing structure 200 includes increased mass at the apex width 202 (or towards the center) and less at the ends (204 and 206), since the edges of the baffle panel are supported by the cabinet sides. By increasing or decreasing the apex width 202, for example, the cabinet sound quality can be changed. In other words, by increasing the center mass of the bracing structure, a measure of stiffness is provided at the center of the baffle panel, which affects the resonant properties of the baffle panel, thereby causing the cabinet sound to change.

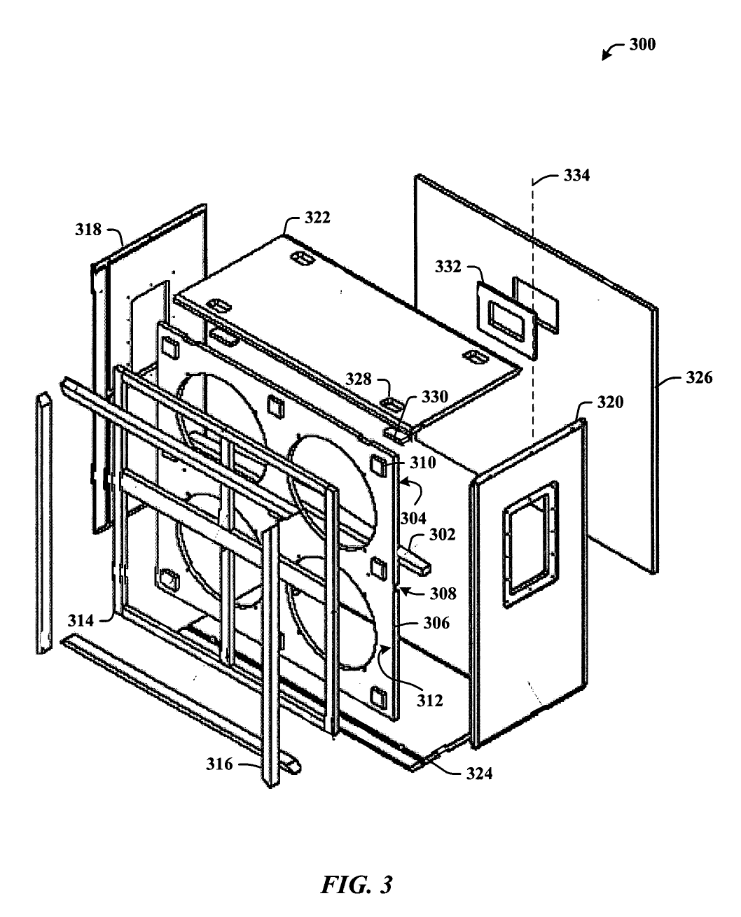

FIG. 3 illustrates an isometric of one exemplary speaker cabinet 300 that employs a bracing structure 302 in accordance with the subject innovation. In this embodiment, the bracing structure 302 is attached horizontally to an inward facing surface 304 of a baffle panel 306 between an upper set and a lower set of speaker mounting holes in a four-speaker cabinet. Furthermore, the inward facing surface 304 of the baffle panel 306 can include a groove or inset 308 into which the bracing structure 302 can be inserted and resides when attached to the baffle panel 306. This reduces the likelihood that the bracing structure 302 could become partially or totally detached from the baffle panel 306 as a result of vibrations during use of the speaker cabinet and/or from handling of the cabinet, for example. The groove 308 also facilitates increased structural integrity of the baffle/bracing structure. The groove 308 can be constructed by many different techniques known to one skilled in the art (e.g., a dado saw when utilizing wood).

In this particular embodiment, the baffle panel 306 includes cleats 310 (e.g., made of wood) on the outside (front or outward facing) surface 312. The cleats 310 (e.g., nine cleats shown here) have attached thereto one part of a hook-and-loop fastener pair (e.g., Velcro™) with mating parts attached to a backside of a grill frame (or grill) 314 allowing the grill 314 to be manually attached to and removed from the front or outward facing surface 312 of the baffle panel 306 of the cabinet 300. The grill 314 can include horizontal and vertical frame members that provide structural support for the cabinet 300, the baffle panel 306, and for handling of the grill 314. The grill 314 can also include grill clothe (not shown) that is stretched over it (e.g., over the outward facing surface of the grill 314) and around the grill edges.

It is to be appreciated that in one implementation, the grill 314 is manufactured in pieces that are assembled, and in another implementation, the grill 314 can be manufacturer as single piece that is cut from a sheet of material having the speaker holes cut out using, for example, a CNC (computer numerical control) machine.

The grill 314 fits inside a filler structure (or filler) 316 that fills out the front of the cabinet 300. The filler 316 provides the capability of giving the desired look to the front of the cabinet 300 (e.g., that the cabinet is made from a thicker material). The filler 316 of the subject invention does not contact the baffle 306. In one implementation, the filler 316 can be structurally prohibited from contacting the baffle 306 by about ¼-inch all the way around the filler perimeter.

Alternatively, the filler 316 can be so constructed in combination with the other cabinet framework to restrict the baffle 306 when the filler 316 is pressed up against the baffle 306.

The cabinet 300 includes a first side panel 318 and a second side panel 320. Across the top and bottom edges of each of the side panels (318 and 320, respectively) are holes (e.g., three) through which fasteners (e.g., screws) can be inserted for fastening the side panels (318 and 320) to mating top and bottom panels (322 and 324, respectively). The joints created by these fastened edges typically receive the most stress during routine audio use, but can experience the most stress during shipment and routine handling. Accordingly, there can be a compromise that is considered between designing the cabinet to survive transportation stresses and yet retaining the desired cabinet tonal quality by not using excessive material dimensions that can reduce or compromise the desired tonal quality.

In one implementation, cleats are not used in the corners as a means to secure the corners together, but a tongue-and-groove interface for the top, bottom and side panels is employed. Thus, each panel that is used to form the cabinet interfaces by at least two, and sometimes three, surfaces that are joined using, for example, glue. As a result, the destructive energy needs to be sufficiently high to damage the cabinet, and hence, change the cabinet tonal quality.

The top panel 322 can include one or more holes 328 (e.g., four) that are sized such that wheels or similar supports of other suitable cabinets can rest therein when stacking another cabinet (e.g., an amplifier) thereon. The holes 328 can be sealed with a seal 330. The wheels or supports of the over-resting cabinet do not rest into the hole 328 at a depth that contacts the underlying seal 330 thereby securing the integrity of the cabinet chamber. Thus, there is no cleat on the back of the baffle 306 or on the underside of the top panel 322, and no cleat on the front surface 312 of the baffle 306, any of which would conventionally be used to secure the baffle 306 into the cabinet structure. Consequently, the effective vibratory surface area of the baffle 306 is larger, which lowers the resonant frequency of the baffle 306, since the baffle 306 now has greater vibrator area (surface) and mass than if cleats had been used.

The back panel 326 includes a jack plate support 332 that mates with an aperture in the back panel 326, is positioned symmetrically along a central vertical axis 334, and towards the upper edge of the back panel 326. The jack plate support 332 facilitates entry and exit of jacks for connecting the speaker cabinet 300 and its internal electronic components. The position can be important. Conventionally, the input jack port is lower in the back panel of a speaker cabinet. In contrast, the speaker cabinet 300 allows the jack plate support 332 to be positioned higher in the back panel 326 since there is no longer a support post. If retained in its original lower position as in conventional cabinet designs and without the conventional sound post, the increased vibration of the connector posts (or ports) can cause problems with maintaining a secure and electrically operational connection.

The design and assembly can be important for cabinet performance. For example, the cleats 310 on the baffle panel 306: the number, placement, size, etc., can all be factors that affect the cabinet sound quality. In one implementation, cleats 310 are not used on the inside surface 304 of the baffle panel 306. In an alternative embodiment, inside cleats are used. The utilization of cleats in the cabinet corners can provide structural integrity in the corners; however, most of the corner support is in the way the joint is designed. Accordingly, if the joint is not good (e.g., butt-jointed versus tongue-and-groove), the fact that the cleat is used may not prevent damage to the corner where, for example, the cabinet is dropped, and more specifically, dropped on the corner. If butt-jointed, it is more likely that cleats will be used extensively to shore up the corner structure. If a tongue-and-groove design is utilized, fewer cleats can be used, if any at all, since the joint provides most of the support.

In another aspect of the novel cabinet design, batting is not used on the inside of the cabinet 300, since it is desired that the cabinet 300 resonate. Traditionally, a speaker cabinet is intended to be acoustically inert. In other words, the cabinet design should not contribute anything to the electrical audio sound output. In contrast, the speaker cabinets described herein (e.g., cabinet 300) are intended to contribute to the overall audio output. In other words, the cabinet 300 is acoustically active, making it sound unique in comparison to another cabinet. The bracing structure 302 is employed to capture traditional qualities that guitar players, for example, expect to hear in a cabinet and that differentiate the cabinet tonal quality from conventional speaker cabinets.

Note that although the speaker cabinet 300 shows a baffle panel 306 with four equally sized speakers, the instant innovation should not be construed to be so limiting. For example, as will be described infra, the bracing structure can be utilized in cabinets with fewer speakers or more speakers. Additionally, the bracing structure 302 can assume different designs based on the control and tonal quality desired, and the cabinet in which it will be employed.

The cabinet 300 can be very similar to conventional cabinets, but with some distinguishing aspects. For example, the cabinet 300 is easier to assemble when employing a baffle that can be “dadoed” into the sides, and the back panel not being removable. Such aspects provide a less costly construction and provide a nicer look. By dadoing in the baffle and sealing the back panel, the whole sound character of the cabinet changes, by increasing the stability and tightness of the cabinet over conventional cabinet designs.

The structural dimensions and types of materials utilized can play into the overall structure and speaker cabinet sound quality. In one example, the sides (318 and 320) are made of Baltic birch having a thickness of about 15 mm; the top and bottom panels (322 and 324) are made of Baltic birch having a thickness of about 15 mm; the baffle panel 306 is made of Baltic birch having a thickness of about 12 mm; the filler 316 is made of Baltic birch having a thickness of about 18 mm; the jack plate support 332 is about 12 mm Baltic birch; a grill cleat 310 is about 9 mm Baltic birch; the grill 314 is about 15 mm Baltic birch; the baffle seal cleats 330 are about 9 mm Baltic birch; and the back panel 326 is made of MDF (medium density fiber) board having a thickness of about one-half inch (or about 12.7 mm).

Note that in one example design change to the back panel, changing the back panel design from ½ inch to ⅝ MDF provides a brighter sounding cabinet and helps to increase low frequency projection.

In another alternative implementation, the baffle panel can be tipped back or angled (e.g., about 15 degrees) toward the back panel, thereby altering the cabinet tonal quality by introducing different audio reflections inside the cabinet. Accordingly, other similar implementations are within contemplation of the subject invention.

It is also to be understood that other materials can be employed separately or in any combination desired with MDF and/or Baltic birch. For example, medium- and high-density overlay plywood (MDO and/or HDO), veneer core hardwood (VC), lumber core plywood, particle board core plywood (PBC), melamine plywood, and high-density maple plywood can also be employed. These are only but a few examples, and are not intended to be limiting in any way as to the type and combinations of materials that can be used for cabinet and/or bracing structure construction.

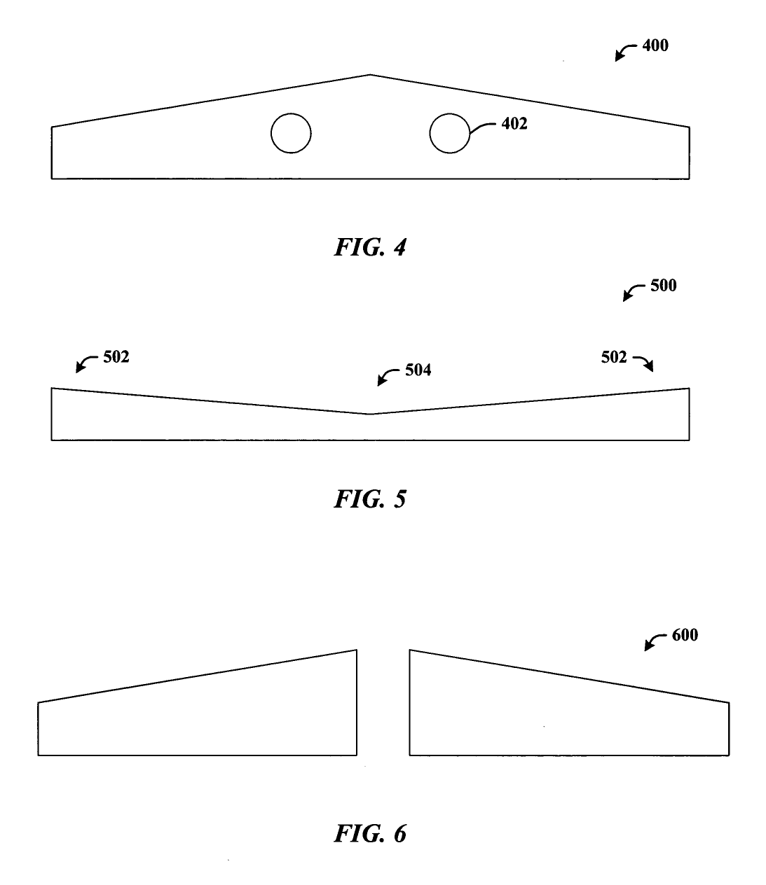

FIG. 4 illustrates a variation on the v-shaped bracing structure 200 of FIG. 2. Here, a bracing structure 400 is v-shaped, but also includes one or more holes 402 positioned through the thickness dimension (as described in FIG. 2). The holes 402 reduce mass and will affect the vibratory characteristics of the bracing structure 400 thereby altering the sound quality of the cabinet in which it is employed.

FIG. 5 illustrates an alternative variation on the v-shaped bracing structure 200 of FIG. 2. Here, a bracing structure 500 uses an inverted v-shape wherein the ends 502 have a greater width than the middle 504. Accordingly, the vibratory characteristics of the brace 500 will thereby alter the sound quality of the baffle panel and the cabinet in which it is employed.

FIG. 6 illustrates an alternative variation on the v-shaped bracing structure 200 of FIG. 2 that employs two separate pieces. Here, a v-shaped bracing structure 600 is essentially the structure 200 of FIG. 2, but cut into two identically shaped pieces that are separately mounted, thereby altering the vibratory characteristics of the baffle panel to which both are attached and the cabinet in which they are employed. In this alternative implementation, zero, one or both parts of the bracing structure 600 can be loaded to produce the desired cabinet sound quality.

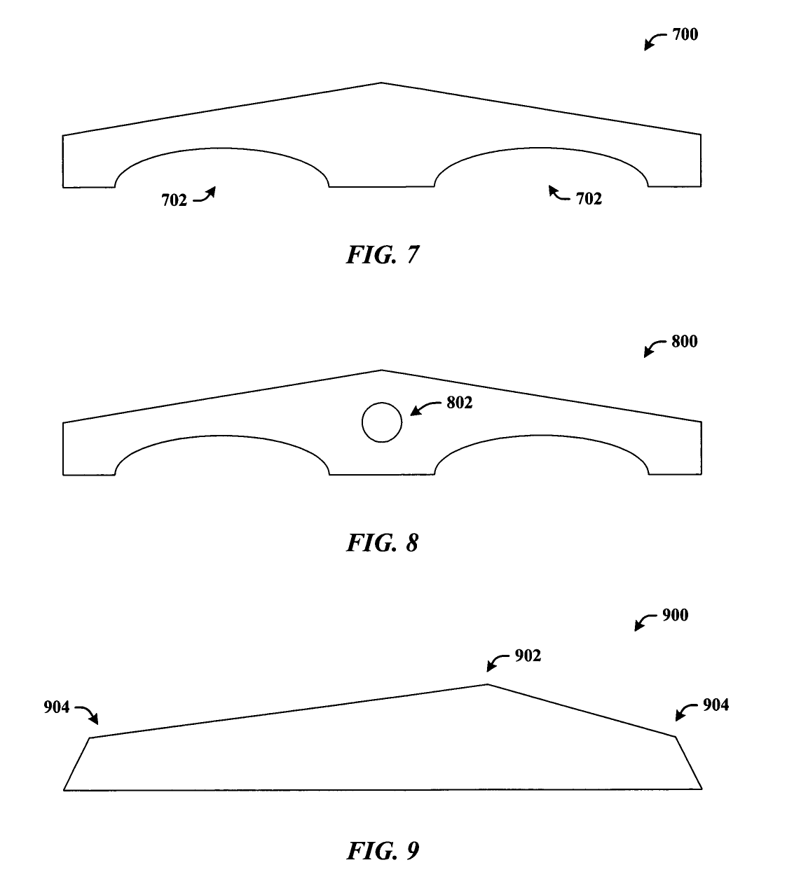

FIG. 7 illustrates an alternative variation on the v-shaped bracing structure 200 of FIG. 2 that removes material at the interfacing edge. Here, the mass of a bracing structure 700 is reduced by removing portions 702 (e.g., elliptical) of material from the bracing structure 700, again, altering the vibrational characteristics of the bracing structure 700, the baffle panel to which it is attached, and the audio characteristics of the cabinet in which it is employed.

FIG. 8 illustrates an alternative bracing structure 800 similar to the v-shaped bracing structure 700 of FIG. 7 that adds a hole 802 through the thickness dimension. The hole 802 will reduce the mass of the structure 800, affecting the vibrational characteristics of the bracing structure 800 and baffle panel, thereby altering the sound quality of the cabinet in which it is employed.

FIG. 9 illustrates an alternative bracing structure 900 similar to the v-shaped bracing structure 200 of FIG. 2 that moves the apex 902 off center thereby shifting its center of mass to a different location (e.g., to the right). Additionally, the ends 904 are sloped. These modifications can affect the vibratory characteristics of the bracing structure 900 thereby altering the vibratory characteristics of the baffle panel to which it is attached and the cabinet in which it is employed.

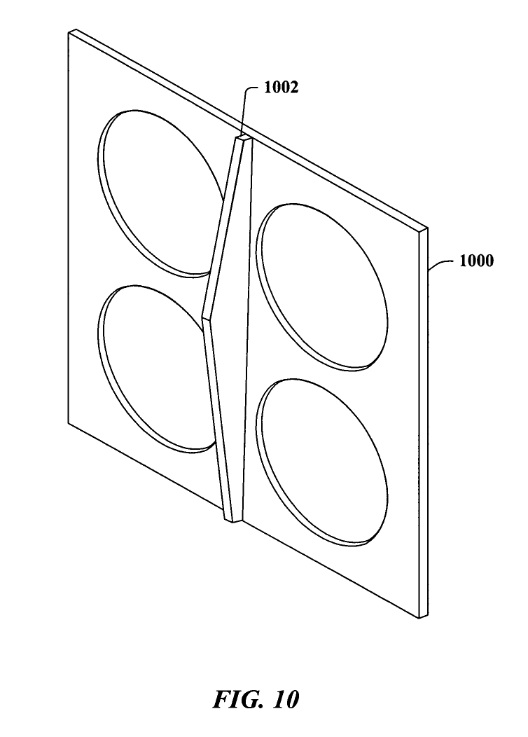

FIG. 10 illustrates a baffle panel 1000 wherein a bracing structure 1002 is attached in a vertical orientation to achieve the desired cabinet tonal quality in accordance with an innovative aspect. The perspective provided here is looking at the inside surface of the baffle panel 1000. Note that the bracing structure 1002 can be attached to the inside surface of the baffle panel 1000 or inserted and affixed into a dadoed slot, as described and shown supra.

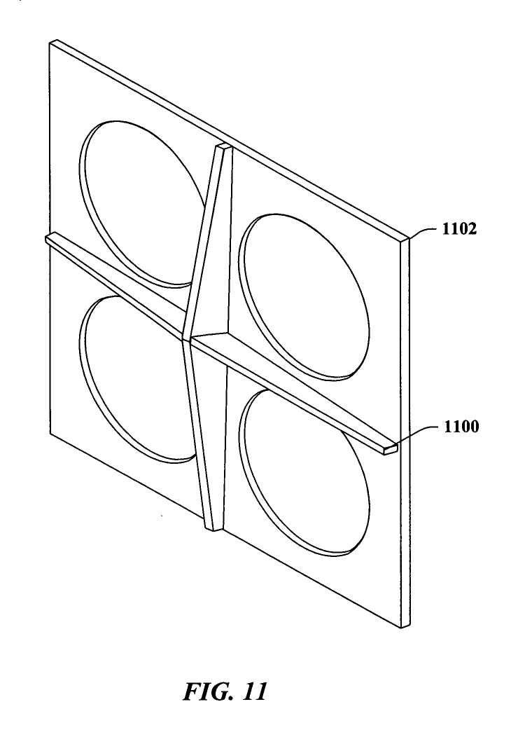

FIG. 11 illustrates a cross bracing structure 1100 that can be employed to control the cabinet tonal quality. As shown, the bracing structure 1100 is designed to be mounted such that a speaker is in each quadrant of a four-speaker cabinet. The bracing structure 1100 can be loaded in one or both directions to the desired forces. As before, the bracing structure 1100 can be attached to the surface of a baffle panel 1102 or inserted and affixed into a dadoed slot (not shown), as described and shown supra.

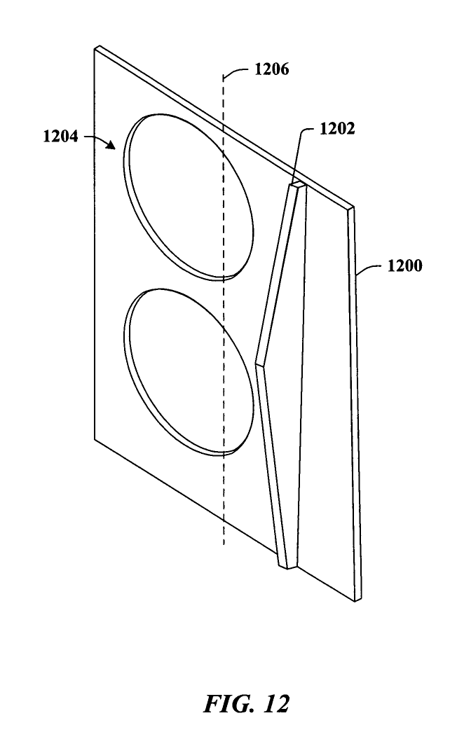

FIG. 12 illustrates a two-speaker cabinet having a baffle panel 1200 to which is attached a bracing structure 1202. Here, the baffle panel 1200 is deigned with the two speaker mounting holes 1204 offset from a central vertical axis 1206 thereby providing space to attach the brace 1202 in a vertical orientation to one side of the speaker mounting holes.

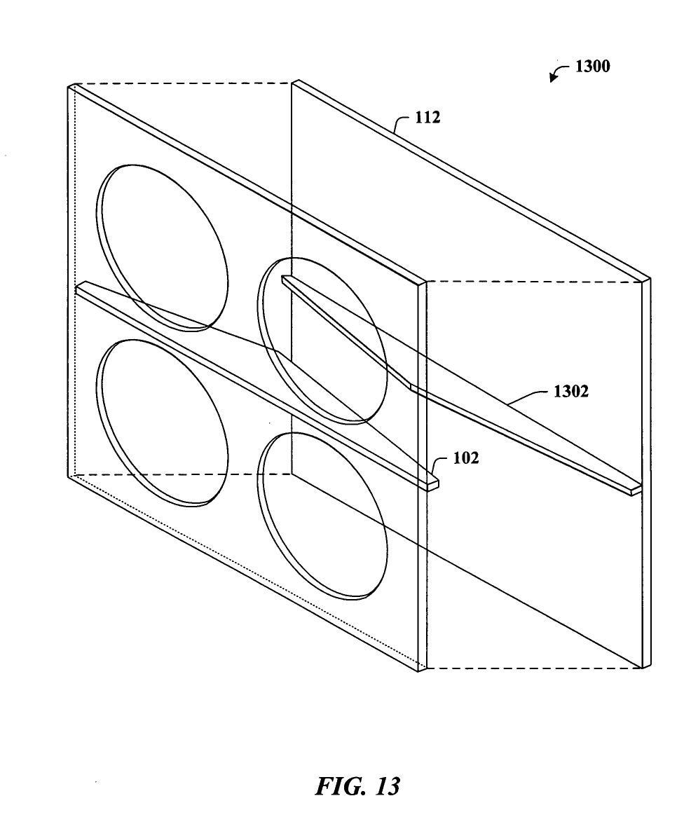

FIG. 13 illustrates a speaker cabinet 1300 that employs a bracing structure 1302 on the back panel 112 for controlling cabinet tonal quality. The back panel bracing structure 1302 can be employed alone or in combination with the baffle panel bracing structure 102. Additionally, although illustrated in a horizontal orientation, the back panel structure 1302 can be oriented vertically or any other desired orientation suitable for affecting cabinet tonal quality. The back panel structure 1302 can be surface mounted on the inside surface of the back panel 112 or inserted and affixed via a dadoed groove (not shown) as described in relation to one embodiment for mounting the baffle panel structure 102.

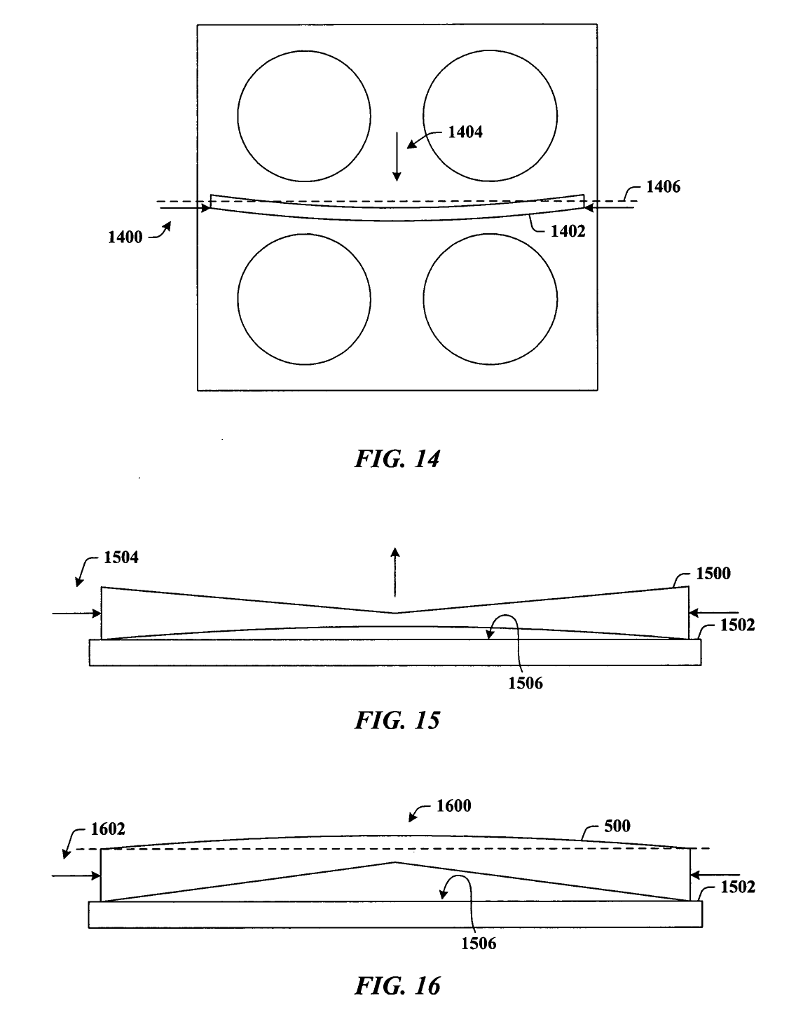

FIG. 14 illustrates a bowing effect that loading 1400 can have on a bracing structure 1402 in accordance with an innovative aspect. Here, the loading 1400 can cause the bracing structure 1402 to bow slightly (e.g., in a downward direction 1404) thereby deforming the bracing structure 1402 along its longitudinal axis 1406.

FIG. 15 illustrates a top-down view of a bracing structure 1500 as mounted on a baffle panel 1502 and the outward bow that can be exhibited in accordance with the subject invention. Here, the compressive loading forces 1504 and the methodology employed to attach the bracing structure 1500 (similar to bracing structure 500 of FIG. 5) can cause bowing of the bracing structure 1500 away from the inside surface 1506 of the baffle panel 1502 (where the bracing structure 1500 is surface-mounted). As indicated hereinabove, the bracing structure 1500 can also be inserted into and attached via a dadoed groove (not shown).

FIG. 16 illustrates a top-down view of the bracing structure 500 of FIG. 5 as mounted on the baffle panel 1502, and the outward bow 1600 that can be exhibited in accordance with another aspect. Here, the bracing structure 500 is mounted in an inverted fashion. The compressive loading forces 1602 and the methodology employed to attach the bracing structure 500 can cause bowing of the bracing structure 500 away from the inside surface 1506 of the baffle panel 1502 (where the bracing structure 500 is surface-mounted). As indicated hereinabove, the bracing structure 500 can also be inserted into and attached via a dadoed groove (not shown).

As shown and described, the bracing structure (or brace) can be of many different dimensions of length, width and thickness, materials, etc. The brace can be split, crossed (as in two crossing each other), and include holes to reduce the material mass, etc. For example, a change in thickness (e.g., from 15 mm to 12 mm) can produce a different overall speaker cabinet sound. This change, as well as how the brace is attached, and the back panel physics can cause a change in the speaker cabinet tonal quality.

For example, in one implementation, the brace is secured in a dado groove with screws (e.g., three). The screw holes can be equally spaced or spaced differently. In another implementation, a cleat can be placed underneath the brace (which could be at any point along the length to effect its vibratory characteristics), since the brace can actually have a resonant frequency itself which the builder may want to dampen. Thus, the resonant frequency of the brace can be altered by changing its length, thickness, width, mounting technique, type of material, and the use of one or more cleats, for example.

It is to be appreciated by one skilled in the art that there are many parameters associated with the brace, the baffle panel, and back cabinet panel that can be adjusted or modified that will change the sound characteristics of the cabinet to the desired audio output (e.g., a heavy metal cabinet, a classic rock cabinet, a tight/crisp cabinet, a loose sloppy cabinet, etc.).

Up to this point, the description has focused primarily on fixed installations of the bracing structure, rather than adjustable. As will now be described, a manually and/or automatically adjustable bracing implementation can be employed.

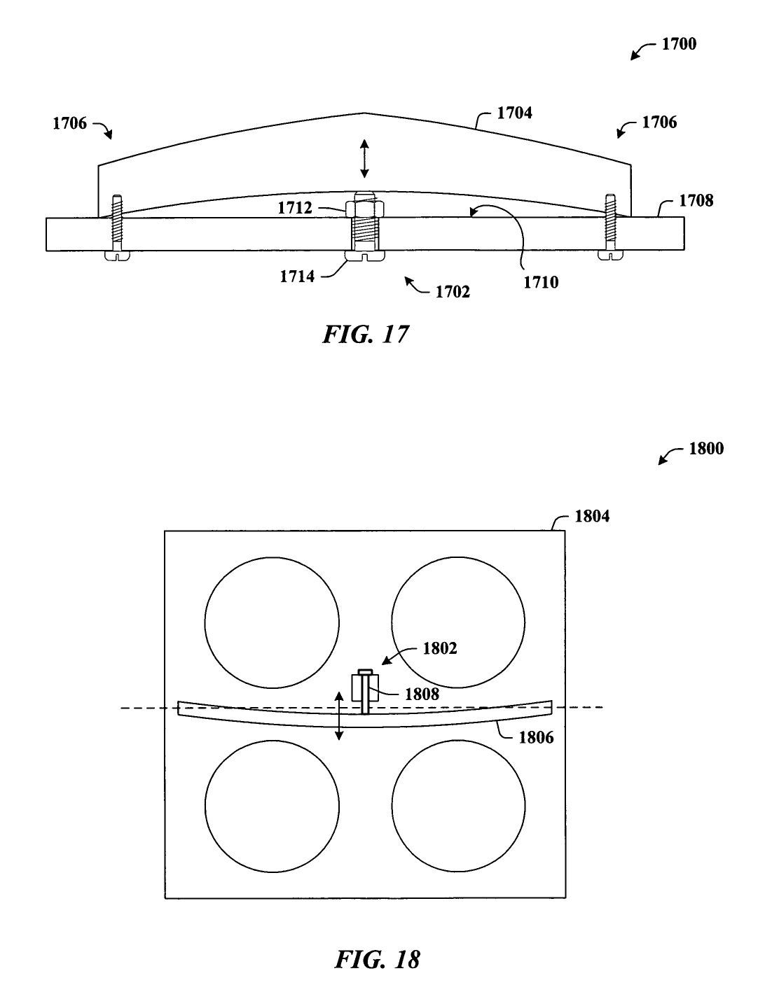

FIG. 17 illustrates a top-down view of a bracing structure system 1700 that employs a manual adjustment mechanism 1702 for adjusting loading thereof to affect the tonal quality of the associated cabinet. For example, an adjustable screw mechanism can be employed to impact a bracing structure 1704 at the desired location (e.g., the approximate center) and thereby change its vibratory (e.g., resonant frequency) characteristics. In the implementation of FIG. 17, only the ends 1706 of the bracing structure 1704 are secured to a baffle panel 1708, such that the bracing structure 1704 can be flexed in a bowed position away from an inside surface 1710 of the baffle panel 1708. The manual adjustment mechanism 1702 is secured on the baffle panel 1708 on one end using a locking nut 1712, for example, and contacts the bracing structure 1704 such that by adjusting a screw 1714, the bow in the bracing structure 1704 can be increased or decreased to effect changes in the frequency of the bracing structure 1704, the resonant frequency of the baffle panel 1708, and thus, the overall cabinet tonal characteristics.

FIG. 18 illustrates a side view of a bracing structure and baffle panel system 1800 that employs a manual adjustment mechanism 1802 for adjusting loading to affect the tonal quality of the associated speaker cabinet. Here, the adjustment mechanism 1802 mounts on a baffle panel 1804 in a position suitable for impacting a side of the bracing structure 1806. When extended, the adjustment mechanism 1802 contacts and pushes against a side of the bracing structure 1806 to create a bow effect which causes a change in the tonal characteristics of the associated speaker cabinet.

The adjustment mechanism 1802, as before, can be a screw-driven device wherein a user turns a screw 1808 for the desired tonal effect. Once adjusted, the screw can be locked down using a locking nut (not shown) so that during use, the desired tonal quality does not change due to vibration, handling, etc.

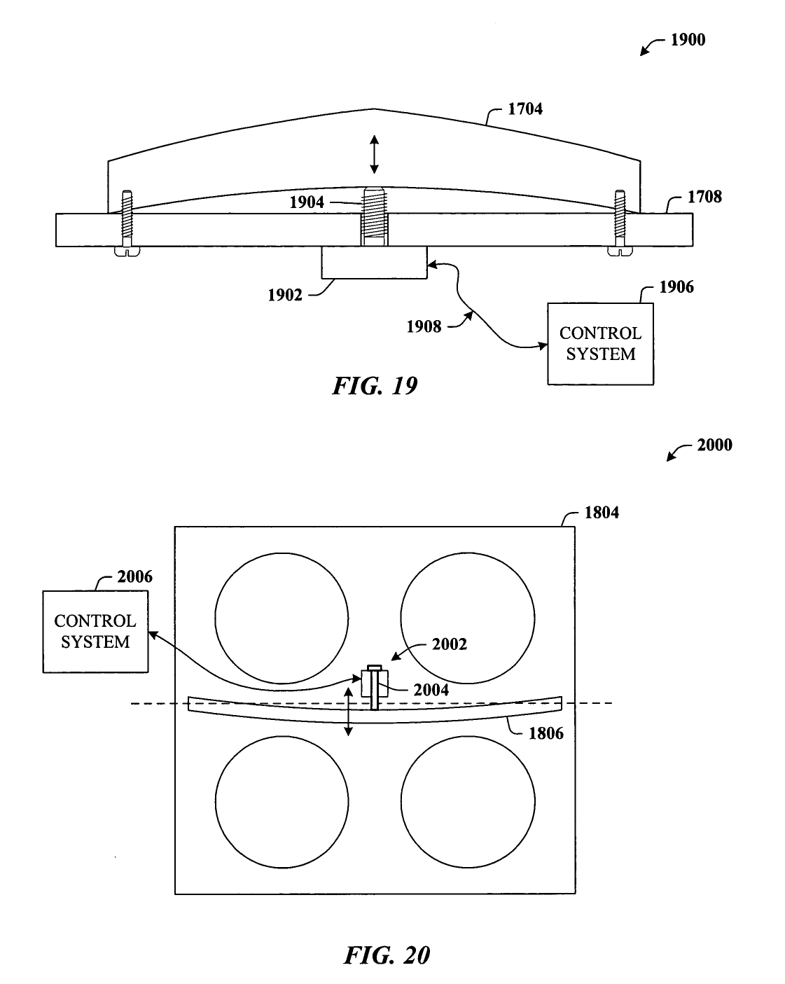

It is within contemplation of the subject invention that the cabinet tonal quality being mechanically adjustable, can also be automatically adjustable. FIG. 19 illustrates an exemplary implementation of an automated tonal control mechanism 1900 for controlling the speaker cabinet tonal quality. In one automated implementation, an electromechanical interface 1902 (e.g., a stepper motor) having suitable specifications (e.g., resolution, lightweight, accurate, . . . ) can be employed to drive a screw 1904 electrically and with precision, thereby allowing the tonal quality to be adjusted. The interface 1902 can communicate with a control system 1906 via a wired connection 1908 and/or a wireless communication link (not shown).

Applying the automated control mechanism 1900 to the bracing structure implementation of FIG. 17, the electromechanical interface 1902 can be fastened to the baffle panel 1708, and drives the screw 1904 to increase or decrease the stress on the bracing structure 1704 thereby changing the tonal quality accordingly.

FIG. 20 illustrates an alternative automated implementation 2000 for cabinet sound quality control in accordance with the subject innovation. Applying an electromechanical interface 2002 to the bracing structure implementation of FIG. 18, the electromechanical interface 2002 can be fastened to the baffle panel 1804, and drives a screw 2004 to increase or decrease the stress on the bracing structure 1806 thereby changing the tonal quality accordingly.

In yet another embodiment, the electromechanical interface 2002 can be replaced with a solenoid-operated interface, such that control of the solenoid drives application of the desired stress on the bracing structure 1806.

In any case, the electromechanical interface 2002 can communicate with a control system 2006 for control thereof in order to obtain the desired cabinet tonal quality.

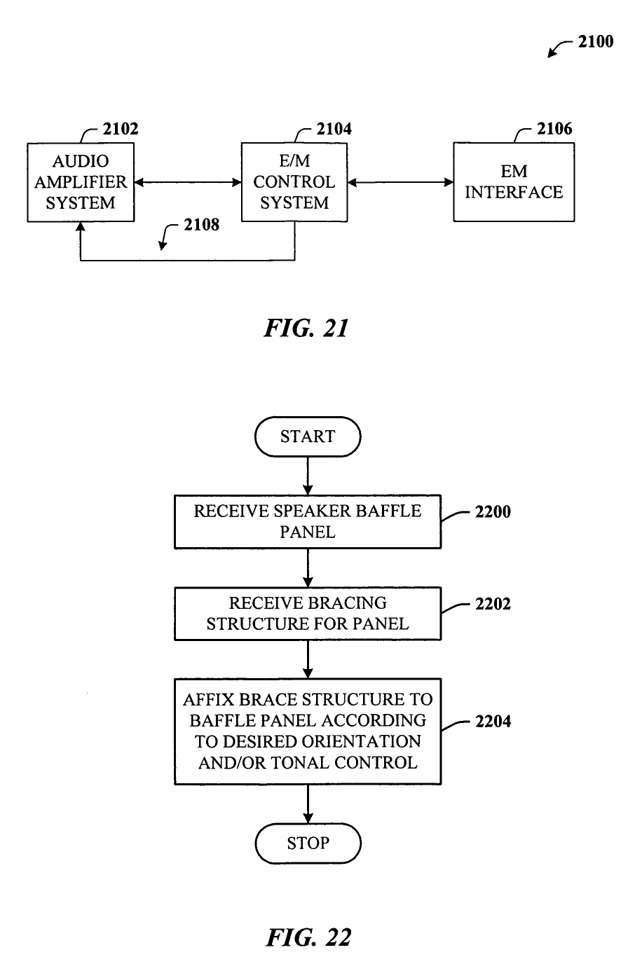

FIG. 21 illustrates a schematic block diagram of a cabinet tonal control system 2100 wherein an audio amplifier 2102 interfaces to the control system 2104 of the electromechanical (EM) interface 2106 for control (e.g., feedback) of the cabinet tonal quality in accordance with another aspect. In this implementation, the adjustment can be linked with audio signal output of the amplifier system 2102 such that as the amplifier volume increases, for example, the corresponding increase in voltage at the output is sensed such that the bracing structure is controlled to tighten the baffle panel as the volume increases. Alternatively, or in addition thereto, a feedback connection 2108 can be employed to provide additional control of the speaker tonal quality. These are only but a few examples of the flexibility that can be employed in accordance with the invention, and are not to be construed as limiting in any way. For example, given such control capability, the tonal characteristics of the speaker enclosure can also be controlled dynamically as the volume increase or decreases.

FIG. 22 illustrates a flow diagram that represents a methodology of controlling speaker cabinet tonal quality in accordance with an innovative aspect. While, for purposes of simplicity of explanation, the one or more methodologies shown herein, e.g., in the form of a flow chart or flow diagram, are shown and described as a series of acts, it is to be understood and appreciated that the subject innovation is not limited by the order of acts, as some acts may, in accordance therewith, occur in a different order and/or concurrently with other acts from that shown and described herein. Moreover, not all illustrated acts may be required to implement a methodology in accordance with the innovation.

At 2200, a speaker baffle panel of a speaker cabinet is received. At 2202, a bracing structure (e.g. a v-shaped bracing structure) is received. At 2204, the bracing structure is affixed to the baffle panel according to the desired orientation and/or tonal control.

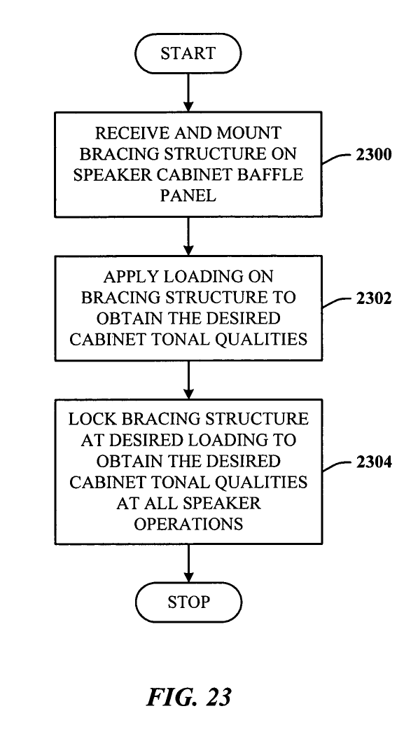

FIG. 23 illustrates a flow diagram that represents a methodology of maintaining speaker cabinet tonal quality in accordance with an innovative aspect. At 2300, a bracing structure is received and mounted on a speaker baffle panel. At 2302, loading is applied to the bracing structure to obtain the desired cabinet tonal qualities. At 2304, the loading of the bracing structure is locked in to obtain the desire cabinet tonal qualities at all speaker operations.

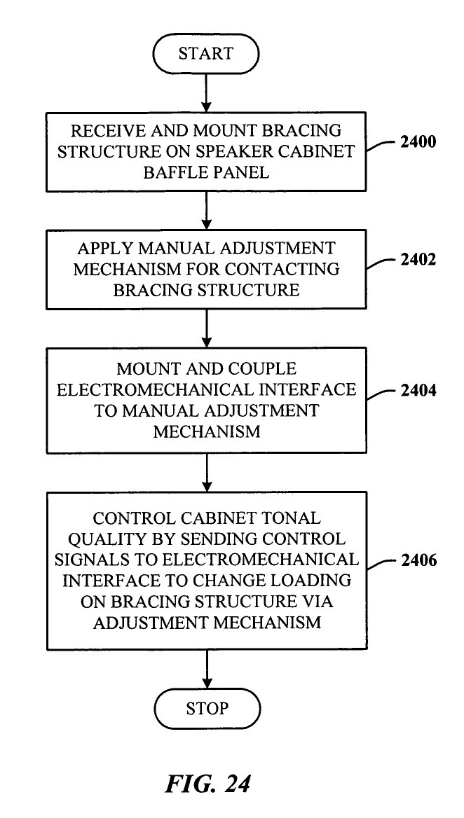

FIG. 24 illustrates a flow diagram that represents a methodology of automatically adjusting speaker cabinet tonal quality in accordance with an innovative aspect. At 2400, a bracing structure is received and mounted on a speaker baffle panel. At 2402, a manual adjustment mechanism is mounted and adjusted for contacting the bracing structure. At 2404, an electromechanical interface mechanism is mounted and coupled to the manual adjustment mechanism. At 2406, cabinet tonal quality is controlled by sending signals to the electromechanical interface to change loading on the bracing structure via the adjustment mechanism.

It is to be appreciated that speakers of any size and number (e.g., one, two, three, four, etc.) can be employed with the bracing structures described herein.

As indicated above multiple bracing structures can be employed. Alternatively, a bracing structure can be attached off-center of the baffle panel. Note that a goal is to inhibit movement at the center of the baffle panel where the baffle is supported the least. However, it is within contemplation of the invention that the bracing structure need not be centered in all instances. For example, in another implementation, the brace is affixed top the baffle in an off-center orientation or position. This can have a reduced effect on cabinet tonal quality, but can offer a more granular control of the cabinet sound.

What has been described above includes examples of the disclosed innovation. It is, of course, not possible to describe every conceivable combination of components and/or methodologies, but one of ordinary skill in the art may recognize that many further combinations and permutations are possible. Accordingly, the innovation is intended to embrace all such alterations, modifications and variations that fall within the spirit and scope of the appended claims. Furthermore, to the extent that the term “includes” is used in either the detailed description or the claims, such term is intended to be inclusive in a manner similar to the term “comprising” as “comprising” is interpreted when employed as a transitional word in a claim.

What is claimed is:

1. A speaker enclosure, comprising:
a panel for facilitating support of a speaker; and
a bracing structure attached to and extending across the panel for controlling tonal characteristics of the speaker enclosure.

2. The enclosure of claim 1, wherein the bracing structure comprises at least two pieces.

3. The enclosure of claim 1, wherein the bracing structure is oriented one of horizontally and vertically.

4. The enclosure of claim 1, wherein the bracing structure is compressively loaded along a longitudinal axis.

5. The enclosure of claim 1, wherein the panel is one of a baffle panel and a back panel.

6. The enclosure of claim 1, further comprising a back panel that in combination with the bracing structure causes a change in the tonal characteristics of the speaker enclosure.

7. The enclosure of claim 1, wherein the bracing structure attaches to the panel at a point that is between a top panel, a bottom panel, and side panels of the speaker enclosure.

8. The enclosure of claim 1, wherein the bracing structure attaches to an inside surface of the panel.

9. The enclosure of claim 1, wherein the bracing structure includes greater mass near a center than near an end.

10. The enclosure of claim 1, wherein the bracing structure comprises two or more pieces that facilitate control of the tonal characteristics.

11. The enclosure of claim 1, wherein the speaker enclosure is acoustically active.

12. A speaker cabinet, comprising:
a baffle panel for supporting a speaker; and
a bracing structure attached to and extending across the baffle panel between outside cabinet panels for controlling tonal characteristics of the speaker cabinet.

13. The cabinet of claim 12, further comprising a manual adjustment mechanism for manually adjusting a load on the bracing structure.

14. The cabinet of claim 12, further comprising an electromechanical adjustment mechanism for dynamically adjusting a load on the bracing structure.

15. The cabinet of claim 12, wherein a back panel of the outside panels of the speaker cabinet includes at least one of a desired dimension and material that in combination with the bracing structure facilitates changing the tonal characteristics of the speaker cabinet.

16. The cabinet of claim 12, wherein the bracing structure is attached to the baffle panel via an inset groove.

17. A method of controlling tonal quality of a speaker cabinet, comprising:
providing a baffle panel for supporting one or more speakers;
mounting a bracing structure across the baffle panel between outside cabinet panels for controlling tonal characteristics of the speaker cabinet; and
loading the bracing structure to obtain a desired tonal quality of the speaker cabinet.

18. The method of claim 17, the act of loading is performed dynamically to achieve the desired tonal quality based on audio volume.

19. The method of claim 17, further comprising at least one of the acts of:
changing construction and material of a back panel in combination with the bracing structure to control the tonal characteristics; and
mounting a second bracing structure to the back panel for adding to controlling of the tonal characteristics of the speaker cabinet.

20. The method of claim 17, further comprising an act of maintaining the desired tonal characteristics of the speaker cabinet throughout operation of the one or more speakers.
